(19) United States
(12) Patent Application Publication
(10) Pub. No.: US 2025/0248240 A1
(43) Pub. Date: Jul. 31, 2025

(54) DISPLAY PANEL, MANUFACTURING METHOD THEREFOR, AND DISPLAY APPARATUS

(71) Applicants: BOE Technology Group Co., Ltd., Beijing (CN); Mianyang BOE Optoelectronics Technology Co., Ltd., Mianyang, Sichuan (CN)

(72) Inventors: Shang WANG, Beijing (CN); Chaochao SUN, Beijing (CN); Le PENG, Beijing (CN); Baicheng ZHENG, Beijing (CN); Shijie CAO, Beijing (CN); Gang YIN, Beijing (CN); Yaofang SUN, Beijing (CN); Wenlei MIAO, Beijing (CN)

(73) Assignees: Mianyang BOE Optoelectronics Technology Co., Ltd., Mianyang, Sichuan (CN); BOE Technology Group Co., Ltd., Beijing (CN)

(21) Appl. No.: 18/854,161

(22) PCT Filed: May 17, 2023
(86) PCT No.: PCT/CN2023/094861

§ 371 Date: Oct. 4, 2024

(30) Foreign Application Priority Data
Jun. 14, 2022 (CN) 202210672172.8

(51) Int. Cl. H10K 59/127; H10K 59/12; H10K 59/80

(52) U.S. Cl. CPC H10K 59/1275; H10K 59/1201; H10K 59/80522

(57) ABSTRACT

A display panel, including: a driving backplane, provided with a display region and a peripheral region located at a periphery of the display region; a first electrode layer, located on a side of the driving backplane and comprising an adapter electrode with an orthographic projection located in the peripheral region; a pixel definition layer, located on a side of the first electrode layer away from the driving backplane; a light-emitting functional layer, located on a side of the pixel definition layer away from the driving backplane, where an orthographic projection of the light-emitting functional layer covers the display region, an edge of the orthographic projection of the light-emitting functional layer is located in the peripheral region, and an orthographic projection of the adapter electrode is located outside the orthographic projection of the light-emitting functional layer; and a second electrode layer.

### CROSS-REFERENCE TO RELATED APPLICATIONS

The present application is a U.S. national stage of International Application No. PCT/CN2023/094861, filed on May 17, 2023, and claims priority to Chinese Patent Application No. 202210672172.8 entitled “Display panel and manufacturing method therefor, and display apparatus”, filed on Jun. 14, 2022, and the entire contents of both of which are incorporated herein by reference.

### TECHNICAL FIELD

The present disclosure relates to the field of display technology, and in particular, to a display panel and manufacturing method therefor, and a display apparatus.

### BACKGROUND

In the display technology, an organic light emitting diode (OLED) display panel is widely recognized as a third generation display technology after a liquid crystal display (LCD) due to its numerous advantages such as lightness and thinness, active light emission, fast response speed, wide viewing angle, rich color, high brightness, low power consumption, and resistance to high and low temperatures.

In order to improve the display effect of the display apparatus, in the manufacturing process of the existing display panel, for the forming of the light-emitting functional layer, the mask is close to the substrate as much as possible to ensure the accuracy of the evaporation position. In this way, although the accuracy of the evaporation position is improved, and the display effect of the display apparatus is improved, some new problems are also generated.

It should be noted that the information disclosed in the above background part is only used to enhance the understanding of the background of the present disclosure, and therefore may include information that does not constitute the related art known to those of ordinary skill in the art.

### SUMMARY

An objective of the present disclosure is to provide a display panel and a manufacturing method therefor, and a display apparatus, which can improve the yield while ensuring the display effect.

According to a first aspect of the present disclosure, there is provided a display panel, including:
a driving backplane, provided with a display region and a peripheral region located at a periphery of the display region;
a first electrode layer, located on a side of the driving backplane and including an adapter electrode with an orthographic projection located in the peripheral region;
a pixel definition layer, located on a side of the first electrode layer away from the driving backplane;
a light-emitting functional layer, located on a side of the pixel definition layer away from the driving backplane, where an orthographic projection of the light-emitting functional layer covers the display region, an edge of the orthographic projection of the light-emitting functional layer is located in the peripheral region, and an orthographic projection of the adapter electrode is located outside the orthographic projection of the light-emitting functional layer; and
a second electrode layer, located on a side of the light-emitting functional layer away from the driving backplane and connected to the adapter electrode.

In some embodiments of the present disclosure, the light-emitting functional layer includes:
a first common film layer, located on a side of the pixel definition layer away from the driving backplane, where an orthographic projection of the first common film layer covers the display region, an edge of the orthographic projection of the first common film layer is located in the peripheral region, and the orthographic projection of the adapter electrode is located outside the orthographic projection of the first common film layer;
a light-emitting material layer, located on a side of the first common film layer away from the driving backplane, and including a plurality of light-emitting material units with orthographic projections located in the display region; and
a second common film layer, located on a side of the light-emitting material layer away from the driving backplane, where an orthographic projection of the second common film layer covers the display region, an edge of the orthographic projection of the second common film layer is located in the peripheral region, and the orthographic projection of the adapter electrode is located outside the orthographic projection of the second common film layer.

In some embodiments of the present disclosure, the adapter electrode is provided with a first edge close to the display region and a second edge away from the display region; and
a distance between the edge of the orthographic projection of the light-emitting functional layer and an orthographic projection of the first edge is greater than or equal to 20 μm.

In some embodiments of the present disclosure, a distance between the edge of the orthographic projection of the light-emitting functional layer and an edge of the display region is greater than or equal to 60 μm and less than or equal to 180 μm.

In some embodiments of the present disclosure, a distance between the orthographic projection of the first edge and an edge of the display region is greater than or equal to 160 μm and less than or equal to 200 μm.

In some embodiments of the present disclosure, an edge of an orthographic projection of the pixel definition layer is located between the orthographic projection of the first edge and an orthographic projection of the second edge.

In some embodiments of the present disclosure, a distance between the edge of the orthographic projection of the pixel definition layer and the orthographic projection of the first edge is greater than or equal to 20 μm.

In some embodiments of the present disclosure, the adapter electrode is provided with a first edge close to the display region;
a distance between the edge of the orthographic projection of the light-emitting functional layer and an edge of the display region is a first distance, and a distance between an orthographic projection of the first edge and the edge of the display region is a second distance;
the second distance is greater than the first distance, and a ratio of the second distance to the first distance is greater than or equal to 1.1 and less than or equal to 1.5.

In some embodiments of the present disclosure, a distance between an edge of an orthographic projection of the pixel definition layer and the edge of the display region is a third distance; and
the third distance is greater than the second distance, and a ratio of the third distance to the second distance is greater than or equal to 1.1 and less than or equal to 1.5.

According to a second aspect of the present disclosure, there is provided a method for manufacturing a display panel, the method including:
forming a driving backplane, where the driving backplane is provided with a display region and a peripheral region located at a periphery of the display region;
forming a first electrode layer on a side of the driving backplane, where the first electrode layer includes an adapter electrode with an orthographic projection located in the peripheral region;
forming a pixel definition layer on a side of the first electrode layer away from the driving backplane;
forming a light-emitting functional layer on a side of the pixel definition layer away from the driving backplane by using at least one mask, where an orthographic projection of the light-emitting functional layer covers the display region, an edge of the orthographic projection of the light-emitting functional layer is located in the peripheral region, and an orthographic projection of the adapter electrode is located outside the orthographic projection of the light-emitting functional layer; and
forming a second electrode layer on a side of the light-emitting functional layer away from the driving backplane, where the second electrode layer at least covers the light-emitting functional layer and is connected to the adapter electrode.

In some embodiments of the present disclosure, forming the light-emitting functional layer on the side of the pixel definition layer away from the driving backplane by using a mask includes:
providing a first mask on a side of the pixel definition layer away from the driving backplane, and forming a first common film layer by using the first mask, where the first mask is provided a first evaporation hole, an orthographic projection of the first evaporation hole covers the display region, an edge of the orthographic projection of the first evaporation hole is located in the peripheral region, and an orthographic projection of the adapter electrode is located outside the orthographic projection of the first evaporation hole;
providing a second mask on a side of the first common film layer away from the driving backplane, and forming a light-emitting material layer by using the second mask, where the second mask is provided with a plurality of second evaporation holes, and orthographic projections of the plurality of second evaporation holes are located in the display region; and
providing a third mask on a side of the light-emitting material layer away from the driving backplane, and forming a second common film layer by using the third mask, where the third mask is provided with a third evaporation hole, an orthographic projection of the third evaporation hole covers the display region, an edge of the orthographic projection of the third evaporation hole is located in the peripheral region, and the orthographic projection of the adapter electrode is located outside the orthographic projection of the third evaporation hole

According to a third aspect of the present disclosure, there is provided a display apparatus, including the display panel according to the first aspect.

The embodiments of the present disclosure at least include the following technical effects.

In the embodiments of the present disclosure, during forming the light-emitting functional layer, the distance between the first mask and the substrate is narrowed to ensure the accuracy of the evaporation position. Meanwhile, since the orthographic projection of the adapter electrode is located outside the orthographic projection of the light-emitting functional layer, the overlapping region between a part of the first mask close to the edge of the hole and the adapter electrode in the thickness direction of the driving backplane can be effectively reduced, so that the formation of the equivalent capacitance can be weakened, so as to weaken the phenomenon that the electrostatic charge is released at the edge of the hole when the first mask is removed, thus weakening the situation that related film layers are damaged by the electrostatic charge, and improving the yield of the display panel.

It is to be understood that both the foregoing general description and the following detailed description are exemplary and explanatory only, and are not limitations on the present disclosure.

### BRIEF DESCRIPTION OF THE DRAWINGS

The accompanying drawings, which are incorporated in and constitute a part of the description, illustrate embodiments consistent with the present disclosure and together with the description serve to explain the principles of the present disclosure. Obviously, the drawings in the following description are some embodiments of the present disclosure, and for those of ordinary skill in the art, other drawings can also be obtained from these drawings without creative efforts.

FIG. 1 is a schematic cross-sectional structural diagram of a display panel according to some embodiments of the present disclosure.

FIG. 2 is a schematic cross-sectional structural diagram of a display panel when manufacturing a light-emitting functional layer according to some embodiments of the present disclosure.

FIG. 3 is a schematic cross-sectional structural diagram of a display panel according to the related art.

FIG. 4 is a schematic top view structural diagram of a display panel according to the related art.

FIG. 5 is a schematic top view structural diagram of a display panel according to some embodiments of the present disclosure.

FIG. 6 is a schematic flowchart of a method for manufacturing a display panel according to some embodiments of the present disclosure.

### DETAILED DESCRIPTION

Example embodiments will now be described more fully with reference to the accompanying drawings. Example embodiments, however, can be implemented in various forms and should not be construed as limited to the embodiments set forth herein; by contrast, these embodiments are provided so that the present disclosure will be thorough and complete, and will fully convey the concept of example embodiments to those skilled in the art. The same reference numerals in the drawings denote the same or similar structures, and thus their detailed descriptions will be omitted. In addition, the drawings are merely schematic illustrations of the present disclosure and are not necessarily drawn to scale.

Although relative terms such as “upper” and “lower” are used in the present description to describe the relative relationship of one component to another component shown in the drawings, these terms are used in the present description for convenience only, for example, according to the example direction described in the accompanying drawings. It will be appreciated that if the device shown in the drawings is flipped upside down, then the “upper” component will become the “lower” component. When a certain structure is “on” the other structure, it may mean that a certain structure is integrally formed on the other structure, or that a certain structure is “directly” provided on the other structure, or that a certain structure is “indirectly” provided on the other structure through another structure.

The terms “a”, “an”, “the”, “said” and “at least one” are used to indicate the presence of one or more elements/components/etc.; the terms “comprising” and “including” are used to indicate an open inclusion and means that there may be additional elements/components/etc., in addition to the listed elements/components/etc.; the terms “first”, “second” and “third” etc. are only used as a marker, not a limitation on the number of its objects.

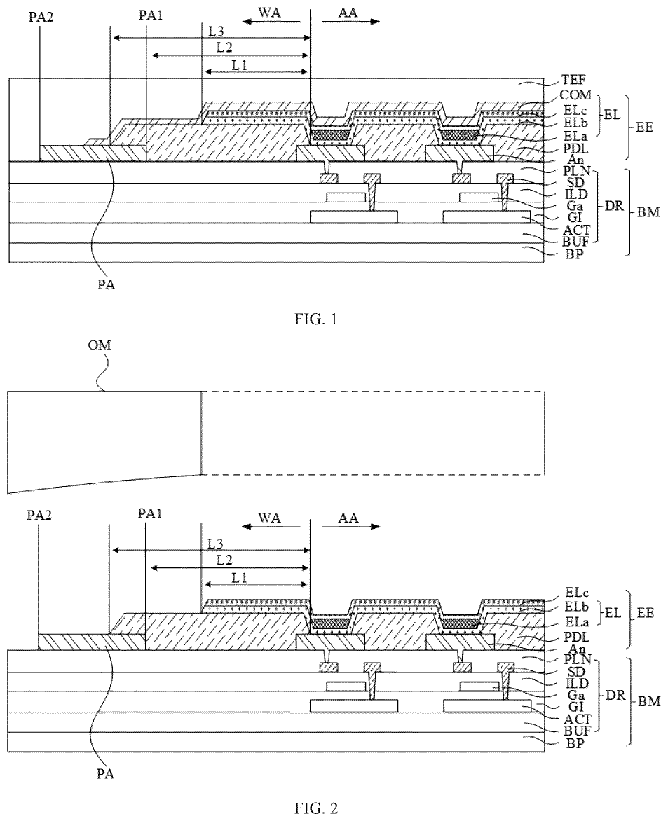

According to some embodiments of the present disclosure, there is provided a display panel. As shown in FIG. 1, the display panel includes a driving backplane BM and a light-emitting layer EE. The driving backplane BM is provided with a display region AA and a peripheral region WA located at a periphery of the display region AA. The driving backplane BM includes a plurality of pixel circuits located in the display region AA. The light-emitting layer EE is located on a side of the driving backplane BM and includes a plurality of light-emitting devices with orthographic projections located in the display region AA. The plurality of pixel circuits are in one-to-one correspondence with the plurality of light-emitting devices, and a light-emitting device is connected to a corresponding pixel circuit, so that the corresponding light-emitting device can be controlled to emit light under the driving of the pixel circuit, so as to realize the display of a screen on the display panel.

Among them, the orthographic projection involved in the present disclosure refers to an orthographic projection on the driving backplane BM. The driving backplane BM includes a substrate BP and a driving layer DR, and the driving layer DR is located between the substrate BP and the light-emitting layer EE. The driving layer DR may be formed within the substrate BP; that is, the driving backplane BM may be a silicon substrate BP. Alternatively, the driving layer DR may be provided independent of the substrate BP. At this time, in some embodiments, the material of the substrate BP may be a glass material such as so-lime glass, quartz glass, and sapphire glass, or may be a metal material such as stainless steel, aluminum, and nickel. In some other embodiments, the material of the substrate BP may be polymethyl methacrylate (PMMA), polyvinyl alcohol (PVA), polyvinyl phenol (PVP), polyether sulfone (PES), polyimide, polyamide, polyacetal, poly carbonate (PC), polyethylene terephthalate (PET), polyethylene napthalate (PEN) or a combination thereof.

In some embodiments, in addition to a single-layer material, the substrate BP may also be a composite of a multi-layer material. For example, in some embodiments, the substrate BP includes a bottom film layer, a pressure-sensitive adhesive layer, a first polyimide layer, and a second polyimide layer that are sequentially stacked.

In the embodiments of the present disclosure, a pixel circuit may include a plurality of transistors and a storage capacitor.

Among them, the transistor may be a thin film transistor. The thin film transistor may be selected from a top gate type thin film transistor, a bottom gate type thin film transistor, or a double gate type thin film transistor. The storage capacitor may be a bipolar plate capacitor or a tripolar plate capacitor. The material of the active layer of the thin film transistor may be an amorphous silicon semiconductor material, a low-temperature polysilicon semiconductor material, a metal oxide semiconductor material, an organic semiconductor material, or another type of semiconductor material. The thin film transistor may be an N-type thin film transistor or a P-type thin film transistor.

It may be understood that, among a plurality of transistors included in a pixel circuit, types of any two transistors may be the same as or different from each other. For example, in some implementations, some of the transistors in a pixel circuit may be N-type transistors, and some of the transistors may be P-type transistors. For another example, in some other implementations, the material of active layers of some transistors in a pixel circuit may be a low-temperature polysilicon semiconductor material, and the material of active layers of some transistors may be a metal oxide semiconductor material.

In some embodiments of the present disclosure, as shown in FIG. 1 or FIG. 2, the driving layer DR includes an insulating buffer layer BUF, a transistor layer, an interlayer dielectric layer ILD, a source-drain metal layer SD, and a planarization layer PLN that are sequentially distributed in a direction away from the substrate BP.

Among them, the material of the interlayer dielectric layer ILD and the material of the planarization layer PLN may organic insulating materials to ensure that a flat surface is provided. The interlayer dielectric layer ILD is provided with a first via hole, so that the transistor layer is connected to a source electrode or a drain electrode of the source-drain metal layer SD through the first via hole. The planarization layer PLN is provided with a plurality of second via holes. The plurality of pixel circuits, the plurality of second via holes, and the plurality of light-emitting devices are in one-to-one correspondence; and a light-emitting device is connected to a corresponding pixel circuit through a corresponding second via hole.

Among them, the material of the insulating buffer layer BUF may be an inorganic insulating material such as silicon oxide and silicon nitride. The insulating buffer layer BUF may be an inorganic material layer with a single layer, or may be an inorganic material layer with multiple layers that are stacked.

In some embodiments, the source-drain metal layer SD may be configured to form a source-drain metal layer SD wiring, such as a power line, a data line, and a connection line, or may be configured to form another polar plate of the storage capacitor. The source-drain metal layer SD may be a source-drain metal layer with a single layer, or may be a source-drain metal layer with two or three layers. For example, the source-drain metal layer SD included in the driving layer DR includes a source-drain metal layer with a single layer.

In the embodiments of the present disclosure, the transistor layer includes a semiconductor layer ACT, a gate insulating layer GI, and a gate metal layer Ga that are stacked between the substrate BP and the interlayer dielectric layer ILD. The positional relationship of the various film layers included in the transistor layer may be determined according to the film layer structure of the thin film transistor.

In some embodiments, as shown in FIG. 1 or FIG. 2, the transistor layer includes a semiconductor layer ACT, a gate insulating layer GI, and a gate metal layer Ga that are sequentially stacked in a direction away from the substrate BP; and the thin film transistor formed in this way is a top gate type thin film transistor. In some other embodiments, the transistor layer includes a gate metal layer Ga, a gate insulating layer GI, and a semiconductor layer ACT that are sequentially stacked in a direction away from the substrate BP; and the thin film transistor formed in this way is a bottom gate type thin film transistor.

In some embodiments, the semiconductor layer ACT may be configured to form an active portion of each transistor included in the pixel circuit, and each active portion includes a channel region and two connection portions (i.e., a source electrode and a drain electrode) located on two sides of the channel region. Among them, the channel region may maintain a semiconductor characteristic, and the semiconductor material corresponding to the two connection portions is partially or completely conductive. The semiconductor layer ACT may be a semiconductor layer with a single layer, or a semiconductor layer with two layers. For example, the semiconductor layer ACT includes a low-temperature polysilicon semiconductor layer.

In some embodiments, the gate metal layer Ga may be configured to form a metal wiring such as a scan line, or may be configured to form a polar plate of the storage capacitor. The gate metal layer Ga may be a gate metal layer with a single layer, or may be a gate metal layer with two or three layers. For example, the gate metal layer Ga includes a gate metal layer with a single layer.

It can be understood that, when the gate metal layer Ga or the semiconductor layer ACT are provided with a structure of multiple layers, the gate insulating layer GI in the transistor layer may be adaptively increased or reduced. For example, in some embodiments, the transistor layer included in the driving layer DR includes a low-temperature polysilicon semiconductor layer ACT, a gate insulating layer GI, and a gate metal layer Ga that are sequentially stacked on the substrate BP.

In some embodiments, the driving layer DR further includes a passivation layer provided between the source-drain metal layer SD and the planarization layer PLN, so as to protect the source-drain metal layer SD through the arrangement of the passivation layer.

In some embodiments, the driving layer DR further includes a shielding layer provided between the insulating buffer layer BUF and the substrate BP. The shielding layer may overlap with a channel region of at least a part of the transistors to shield the light irradiated to the transistor, so that the electrical characteristics of the transistor are stable.

In the embodiments of the present disclosure, the light-emitting device may be an organic electroluminescent diode, a micro light emitting diode, a quantum dot-organic electroluminescent diode, a quantum dot light emitting diode, or another type of light-emitting device.

For example, in some embodiments, the light-emitting device is an organic electroluminescent diode, and the display panel is an OLED display panel. In the following, a feasible structure of a light-emitting device is exemplarily described by taking that the light-emitting device is an organic electroluminescent diode as an example.

As shown in FIG. 1, the light-emitting layer EE includes a first electrode layer An, a pixel definition layer PDL, a light-emitting functional layer EL, and a second electrode layer COM that are sequentially stacked in a direction away from the driving backplane BM. The first electrode layer An includes a plurality of first electrodes distributed at intervals, and orthographic projections of the plurality of first electrodes are located in the display region AA. The light-emitting functional layer EL includes light-emitting units in one-to-one correspondence with the plurality of first electrodes. The second electrode layer COM includes second electrodes in one-to-one correspondence with the plurality of first electrodes. The first electrodes, the light-emitting units, and the second electrodes constitute a light-emitting device.

Among them, the pixel definition layer PDL is provided with a plurality of pixel openings in one-to-one correspondence with the plurality of first electrodes. The first electrode includes an exposed region exposed at a corresponding pixel opening. The exposed region forms a light-emitting region of the corresponding light-emitting device.

Among them, the light-emitting functional layer EL may include one or more of a light-emitting material layer Ela, a hole injection layer, a hole transport layer, an electron blocking layer, a hole blocking layer, an electron transport layer, and an electron injection layer.

For any film layer of the hole injection layer, the hole transport layer, the electron blocking layer, the hole blocking layer, the electron transport layer, and the electron injection layer, since the any film layer may be used as the common film layer of the plurality of light-emitting devices, it may be made by using a mask with an evaporation hole completely covering the display region. Specifically, the first mask OM is provided with a first evaporation hole corresponding to the entire display region AA, and the any film layer may be made in the entire display region AA by using the first evaporation hole in the first mask OM. In this way, the orthographic projection of the common film layer included in the light-emitting functional layer EL covers the display region AA, and the edge of the orthographic projection is located in the peripheral region WA; that is, the orthographic projection of the light-emitting functional layer EL covers the display region AA, and the edge of the orthographic projection of the light-emitting functional layer EL is located in the peripheral region WA. In some embodiments, when the light-emitting functional layer EL includes a plurality of common film layers, some of the common film layers may be directly evaporated within the pixel openings by using the second mask, in addition to evaporation by using the first mask OM, which is not limited in the embodiments of the present disclosure.

For the light-emitting material layer Ela, it may be made by using the second mask. Specifically, the second mask is provided with a plurality of second evaporation holes in one-to-one correspondence with the plurality of pixel openings. The light-emitting material unit may be evaporated within each pixel opening by using the second evaporation hole in the second mask. In this case, the light-emitting material unit includes a red unit, a green unit, and a blue unit. In some embodiments, the light-emitting material layer Ela may also be made by using the first mask described above; and in this case, the light-emitting material layer is a white material layer.

In some embodiments, as shown in FIG. 1, the display panel may further include a thin film encapsulation layer TEF. The thin film encapsulation layer TEF is provided on a side of the light-emitting layer EE away from the substrate BP, and may include an inorganic encapsulation layer and an organic encapsulation layer that are alternately stacked. For example, the thin film encapsulation layer TEF includes a first inorganic encapsulation layer, an organic encapsulation layer, and a second inorganic encapsulation layer that are sequentially stacked on a side of the light-emitting layer EE away from the substrate BP.

The inorganic encapsulation layer can effectively block external moisture and oxygen, so as to avoid degradation of the material caused by intrusion of water and oxygen into the organic light-emitting functional layer EL. The organic encapsulation layer is located between two adjacent inorganic encapsulation layers, so as to realize planarization and reduce the stress between the inorganic encapsulation layers.

Among them, an orthographic projection of an edge of the inorganic encapsulation layer may extend from the display region AA to the peripheral region WA. An orthographic projection of an edge of the organic encapsulation layer may be located between an edge of the display region AA and an edge of the inorganic encapsulation layer.

In the embodiment of the present disclosure, as shown in FIG. 1 or FIG. 2, the light-emitting layer EE further includes an adapter electrode PA with an orthographic projection located in the peripheral region WA. The second electrode layer COM is electrically connected to the adapter electrode PA, thus facilitating conduction between the second electrode layer and an external circuit.

Among them, the adapter electrode PA may be made in the same layer as the first electrode. That is, the first electrode layer An further includes an adapter electrode PA in addition to the first electrode. In some embodiments, the adapter electrode PA may also be located in a different film layer from the first electrode.

Among them, by taking that the adapter electrode PA and the first electrode are made in the same layer as an example, the first electrode and the adapter electrode PA may be formed by means of whole-layer evaporation followed by etching, or may be formed by means of patterning evaporation, or certainly may also be formed in other manners, as long as it is ensured that the orthographic projection of the first electrode is located in the display region AA, and the orthographic projection of the adapter electrode PA is located in the peripheral region WA.

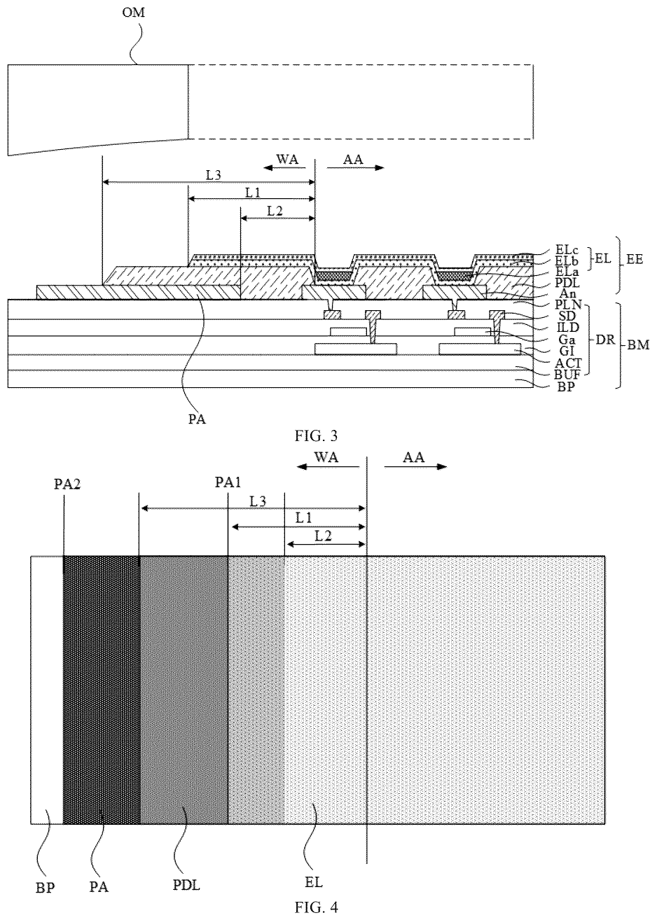

In combination with the above-mentioned film layer structure of the light-emitting functional layer EL, after careful research on forming of the light-emitting functional layer EL in the related art, the inventor finds that: during forming some common film layers of the light-emitting functional layer EL, as shown in FIG. 3 and FIG. 4, the first mask OM provided with the first evaporation hole is usually used; since the first mask OM is close to the substrate BP, and there is an overlapping portion between a part of the first mask OM close to the edge of the hole and the adapter electrode PA in the thickness direction of the substrate BP, an equivalent capacitance is formed to realize charge accumulation. When the first mask OM is removed, as the distance between the first mask OM and the adapter electrode PA is increased, the capacity of the equivalent capacitance for storing the net charge is gradually weakened; and when the distance between the first mask OM and the adapter electrode PA is increased to a certain value, the electrostatic charge may be released at the edge of the hole of the first mask OM, thus damaging the related film layer (such as the insulating buffer layer BUF, the gate insulating layer GI, the interlayer dielectric layer ILD, the passivation layer PVX, etc.), and forming a crack in the related film layer. In this way, it is easy to cause immersion of water vapor along the crack, thus causing a failure of the light-emitting functional layer EL, and reducing the yield of the display panel.

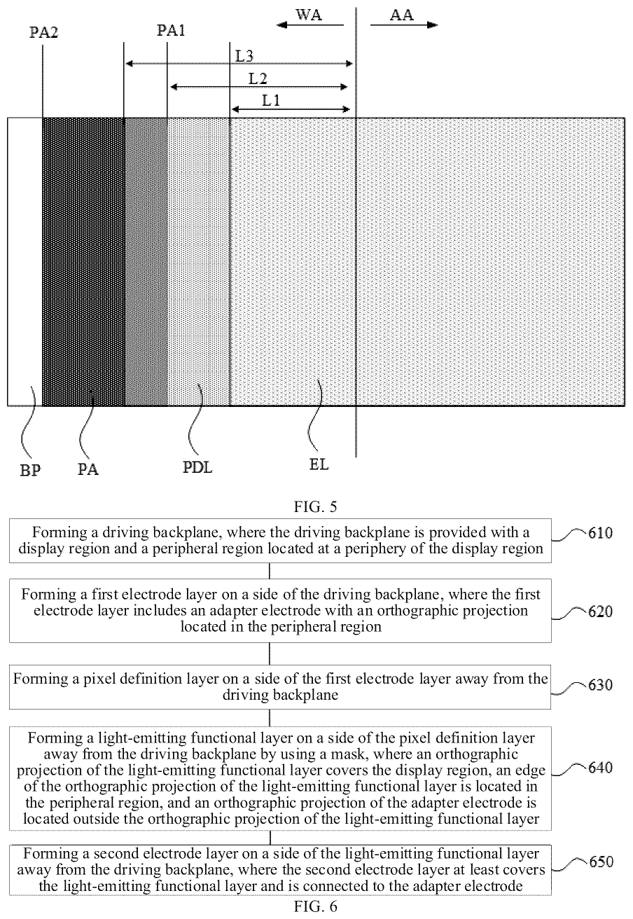

In the present disclosure, when the common film layer of the light-emitting functional layer EL is evaporated by using the first mask OM, in order to avoid an equivalent capacitance formed between the part of the first mask OM close to the edge of the hole and the adapter electrode PA, as shown in FIG. 5, the orthographic projection of the adapter electrode PA is located outside the orthographic projection of the light-emitting functional layer EL. That is, the edge of the orthographic projection of the adapter electrode PA is located within the orthographic projection of the first mask OM.

In this way, during forming the light-emitting functional layer EL, the distance between the first mask OM and the substrate BP is narrowed to ensure the accuracy of the evaporation position. Meanwhile, since the orthographic projection of the adapter electrode PA is located outside the orthographic projection of the light-emitting functional layer EL, the overlapping region between a part of the first mask OM close to the edge of the hole and the adapter electrode PA in the thickness direction of the driving backplane BM can be effectively reduced, so that the formation of the equivalent capacitance can be weakened, so as to weaken the phenomenon that the electrostatic charge is released at the edge of the hole when the first mask is removed, thus weakening the situation that related film layers are damaged by the electrostatic charge, and improving the yield of the display panel.

In combination with the above case that the light-emitting functional layer EL includes common film layers, in some embodiments, as shown in FIG. 1 or FIG. 2, the light-emitting functional layer EL includes a first common film layer ELb, a light-emitting material layer ELa, and a second common film layer ELc. The first common film layer ELb is located on a side of the pixel definition layer away from the driving backplane BM; the light-emitting material layer ELa is located on a side of the first common film layer ELb away from the driving backplane BM, and includes a plurality of light-emitting material units with orthographic projections located in the display region AA; and the second common film layer ELc is located on a side of the light-emitting material layer ELa away from the driving backplane BM.

Among them, the first common film layer ELb may be one or more of a hole injection layer, a hole transport layer, and an electron blocking laye. The second common film layer ELc may be one or more of a hole blocking layer, an electron transport layer, and an electron injection layer.

In combination with the above description, the first common film layer ELb may be evaporated by using the first mask OM, and the second common film layer ELc may be evaporated by using the second mask. The first common film layer ELb may be evaporated by using the second mask, and the second common film layer ELc may be evaporated by using the first mask OM. The first common film layer ELb and the second common film layer ELc may be evaporated both by using the first mask OM. For the case that the first common film layer ELb and the second common film layer ELc include a plurality of film layers, some film layers of the plurality of film layers may be evaporated by using the first mask OM, and the remaining film layers may be evaporated by using the second mask.

For example, the first common film layer ELb and the second common film layer ELc are evaporated both by using the first mask OM. In this case, the orthographic projection of the first common film layer ELb covers the display region AA, the edge of the orthographic projection of the first common film layer ELb is located in the peripheral region WA, and the orthographic projection of the adapter electrode PA is located outside the orthographic projection of the first common film layer ELb. The orthographic projection of the second common film layer ELc covers the display region AA, the edge of the orthographic projection of the second common film layer ELc is located in the peripheral region WA, and the orthographic projection of the adapter electrode PA is located outside the orthographic projection of the second common film layer ELc.

In this way, during forming the first common film layer ELb and the second common film layer ELc, the overlapping region between a part of the first mask OM close to the edge of the hole and the adapter electrode PA in the thickness direction of the driving backboard BM can be both effectively reduced, so that the formation of the equivalent capacitance can be weakened, so as to weaken the phenomenon that the electrostatic charge is released at the edge of the hole when the first mask is removed, and improve the yield of the display panel.

In some embodiments, as shown in FIG. 1, FIG. 2, or FIG. 5, the adapter electrode PA is provided with a first edge PA1 close to the display region AA and a second edge PA2 away from the display region AA. A distance between an edge of an orthographic projection of the light-emitting functional layer EL and an orthographic projection of the first edge PA1, i.e., a difference between L2 and L1, is greater than or equal to 20 μm.

In this way, during forming the light-emitting functional layer EL, the length of the edge of the hole of the first mask OM extending beyond the first edge PA1 is greater than or equal to 20 μm, so that the overlapping region between a part of the first mask OM close to the edge of the hole and the adapter electrode PA in the thickness direction of the driving backplane BM can be further reduced, so as to weaken or even avoid the formation of equivalent capacitance near the edge of the hole of the first mask OM, further improving the yield of the display panel. For example, the distance between the edge of the orthographic projection of the light-emitting functional layer EL and the orthographic projection of the first edge PA1 is 20 μm, 30 μm, 40 μm, 50 μm, etc. That is, during forming the light-emitting functional layer EL, the length of the edge of the hole of the first mask OM extending beyond the first edge PA1 is 20 μm, 30 μm, 40 μm, 50 μm, etc.

Continuing with the above example, the first common film layer ELb and the second common film layer ELc are evaporated both by using the first mask OM. In this case, the distance between the edge of the orthographic projection of the first common film layer ELb or the edge of the orthographic projection of the second common film layer ELc and the orthographic projection of the first edge PA1, i.e., a difference between L2 and L1, is greater than or equal to 20 μm. That is, during forming the first common film layer ELb and dripping into the common film layer, the length of the edge of the hole of the first mask OM extending beyond the first edge PA1 is greater than or equal to 20 μm. For example, during forming the first common film layer ELb and dripping into the common film layer, the length of the edge of the hole of the first mask OM extending beyond the first edge PA1 is 20 μm, 30 μm, 40 μm, 50 μm, etc.

It should be noted that, during adjusting the distance between the edge of the orthographic projection of the light-emitting functional layer EL and the orthographic projection of the first edge PA1, the greater the distance between the edge of the orthographic projection of the light-emitting functional layer EL and the orthographic projection of the first edge PA1, the greater the gap between the adapter electrode PA and the display region AA, so that the width of the peripheral region WA of the display panel is greater. In this way, in order to avoid a wider peripheral region WA of the display panel, the distance between the edge of the orthographic projection of the light-emitting functional layer EL and the orthographic projection of the first edge PA1 may be less than a certain distance. For example, the distance between the edge of the orthographic projection of the light-emitting functional layer EL and the orthographic projection of the first edge PA1 is less than 140 μm.

In some embodiments, the distance L1 between the edge of the orthographic projection of the light-emitting functional layer EL and the edge of the display region AA is greater than or equal to 60 μm and less than or equal to 180 μm. For example, the distance L1 between the edge of the orthographic projection of the light-emitting functional layer EL and the edge of the display region AA is 120 μm.

In this way, by defining the minimum distance between the edge of the orthographic projection of the light-emitting functional layer EL and the edge of the display region AA, the length of the edge of the light-emitting functional layer EL extending beyond the edge of the display region AA can be ensured, and the case that the thickness of the light-emitting functional layer EL is uneven at the edge of the display region AA is avoided. By defining the maximum distance between the edge of the orthographic projection of the light-emitting functional layer EL and the edge of the display region AA, since it is necessary to ensure that the orthographic projection of the adapter electrode PA is located outside the orthographic projection of the light-emitting functional layer EL, the problem that the frame of the display panel is relatively wider due to the relatively greater gap between the orthographic projection of the second edge PA2 of the adapter electrode PA and the display region AA is avoided.

In some embodiments, a distance L2 between the orthographic projection of the first edge PA1 and the edge of the display region AA is greater than or equal to 160 μm and less than or equal to 200 μm. For example, the distance L2 between the orthographic projection of the first edge PA1 and the edge of the display region AA is 180 μm.

In this way, by defining the minimum distance between the orthographic projection of the first edge PA1 and the edge of the display region AA, it can be avoided that the gap between the orthographic projection of the first edge PA1 of the adapter electrode PA and the display region AA is relatively greater, thus achieving the narrow frame of the display panel. By defining the maximum distance between the orthographic projection of the first edge PA1 and the edge of the display region AA, it can be ensured that the light-emitting functional layer EL is provided with a sufficient arrangement space, thus ensuring that the thickness of the light-emitting functional layer EL at the edge of the display region AA is even, and meanwhile, realizing that the orthographic projection of the light-emitting functional layer EL is located outside the orthographic projection of the adapter electrode PA.

Furthermore, in the embodiments of the present disclosure, the pixel definition layer may not cover the adapter electrode PA, or may cover only a part of the adapter electrode PA, or certainly may also completely cover the adapter electrode PA.

When the pixel definition layer does not cover the adapter electrode PA or only covers a part of the adapter electrode PA, the second electrode layer COM can directly cover the adapter electrode PA to realize the connection between the second electrode layer COM and the adapter electrode PA. When the pixel definition layer completely covers the adapter electrode PA or only covers a part of the adapter electrode PA, the second electrode layer COM can be connected to the adapter electrode PA through the via hole penetrating through the pixel definition layer.

Among them, as shown in FIG. 1 or FIG. 2, the pixel definition layer covers a part of the adapter electrode PA. That is, as shown in FIG. 5, an edge of an orthographic projection of the pixel definition layer is located between an orthographic projection of the first edge PA1 and an orthographic projection of the second edge PA2.

In some embodiments, a distance between the edge of the orthographic projection of the pixel definition layer and the orthographic projection of the first edge PA1, i.e., a difference between L3 and L2, is greater than or equal to 20 μm.

In some other embodiments, the adapter electrode PA is provided with a first edge PA1 close to the display region AA. The distance between an edge of an orthographic projection of the light-emitting functional layer EL and an edge of the display region AA is a first distance L1, and a distance between an orthographic projection of the first edge PA1 and the edge of the display region AA is a second distance L2. The second distance L2 is greater than the first distance L1, and a ratio of the second distance L2 to the first distance L1 is greater than or equal to 1.1 and less than or equal to 1.5.

In combination with the manufacturing of the light-emitting functional layer EL, it can be known that the distance between the orthographic projection of the edge of the hole of the first mask OM and the edge of the display region AA is the first distance L1. In this way, it can be ensured that the length of the edge of the hole of the first mask OM extending beyond the adapter electrode PA is at least 0.1 times of the first distance L1, so that it can be ensured that the overlapping region between a part of the first mask OM close to the edge of the hole and the adapter electrode PA in the thickness direction of the driving backplane is reduced, thus weakening or even avoiding the formation of the equivalent capacitance near the edge of the hole of the first mask OM, further improving the yield of the display panel. In addition, since the ratio of the second distance L2 to the first distance L1 is less than or equal to 1.5, in the case that the first distance L1 is determined, the situation that the second distance L2 is relatively greater is avoided, so that the situation that the width of the peripheral region WA of the display panel is relatively greater is avoided, and the narrow frame of the display panel is ensured.

Furthermore, in combination with the cover condition of the pixel definition layer to the adapter electrode PA described in the above embodiments, optionally, the distance between the edge of the orthographic projection of the pixel definition layer and the edge of the display region AA is a third distance L3, the third distance L3 is greater than the second distance L2, and the ratio of the third distance L3 to the second distance L2 is greater than or equal to 1.1 and less than or equal to 1.5.

According to some embodiments of the present disclosure, there is further provided a method for manufacturing a display panel, which can be used to manufacture the display panel described in the above embodiments. As shown in FIG. 6, the method includes the following step 610 to step 650.

In step 610, a driving backplane is formed, where the driving backplane is provided with a display region and a peripheral region located at a periphery of the display region.

In step 620, a first electrode layer is formed on a side of the driving backplane, where the first electrode layer includes an adapter electrode with an orthographic projection located in the peripheral region.

In step 630, a pixel definition layer is formed on a side of the first electrode layer away from the driving backplane.

In step 640, a light-emitting functional layer is formed on a side of the pixel definition layer away from the driving backplane by using at least one mask, where an orthographic projection of the light-emitting functional layer covers the display region, an edge of the orthographic projection of the light-emitting functional layer is located in the peripheral region, and an orthographic projection of the adapter electrode is located outside the orthographic projection of the light-emitting functional layer.

In step 650, a second electrode layer is formed on a side of the light-emitting functional layer away from the driving backplane, where the second electrode layer at least covers the light-emitting functional layer and is connected to the adapter electrode.

In the embodiments of the present disclosure, during forming the light-emitting functional layer, the distance between the first mask and the substrate is narrowed to ensure the accuracy of the evaporation position. Meanwhile, since the orthographic projection of the adapter electrode is located outside the orthographic projection of the light-emitting functional layer, the overlapping region between a part of the first mask close to the edge of the hole and the adapter electrode in the thickness direction of the driving backplane can be effectively reduced, so that the formation of the equivalent capacitance can be weakened, so as to weaken the phenomenon that the electrostatic charge is released at the edge of the hole when the first mask is removed, thus weakening the situation that related film layers are damaged by the electrostatic charge, and improving the yield of the display panel.

In step 610, forming can be performed in combination with the specific structure of the driving backplane described in the above embodiments and with reference to the formation process of each film layer of the driving backplane in the related art, which is not limited in the embodiments of the present disclosure. In step 620, forming can be performed in combination with the positional relationship between the adapter electrode and the first electrode described in the above embodiments, that is, in combination with the forming method, which is not limited in the embodiments of the present disclosure.

In step 640, forming can be performed in combination with the film layer structure of the light-emitting functional layer described in the above embodiments. During forming the light-emitting functional layer, various film layers of the light-emitting functional layer may be formed by using a universal mask, or various film layers of the light-emitting functional layer may be formed by using a plurality of masks.

By taking that the light-emitting functional layer includes a first common film layer, a light-emitting material layer, and a second common film layer that are stacked as an example, a first mask is provided on a side of the pixel definition layer away from the driving backplane, and the first common film layer is formed by using the first mask. The first mask is provided with a first evaporation hole, an orthographic projection of the first evaporation hole covers the display region, an edge of the orthographic projection of the first evaporation hole is located in the peripheral region, and an orthographic projection of the adapter electrode is located outside the orthographic projection of the first evaporation hole. A second mask is provided on a side of the first common film layer away from the driving backplane, and the light-emitting material layer is formed by using the second mask. The second mask is provided with a plurality of second evaporation holes, and orthographic projections of the plurality of second evaporation holes are located in the display region. A third mask is provided on a side of the light-emitting material layer away from the driving backplane, and the second common film layer is formed by using the third mask. The third mask is provided with a third evaporation hole, an orthographic projection of the third evaporation hole covers the display region, the edge of the orthographic projection of the third evaporation hole is located in the peripheral region, and the orthographic projection of the adapter electrode is located outside the orthographic projection of the third evaporation hole.

Among them, the first mask and the third mask may be the same mask, which are merely different names during forming the first common film layer and the second common film layer. In some embodiments, the first mask and the third mask may also be different masks, which is not limited in the embodiments of the present disclosure.

It should be noted that although various steps of the method for manufacturing the display panel in the present disclosure are described in a specific order in the drawings, this does not require or imply that the steps must be performed in the specific order, or all the steps shown must be performed to achieve the desired result. Additionally or alternatively, some steps may be omitted, multiple steps may be combined into one step for execution, and/or one step may be decomposed into multiple steps for execution.

According to some embodiments of the present disclosure, there is further provided a display apparatus, including the display panel described in the above embodiments.

With reference to the display panel described in the above embodiment, for the display apparatus using the display panel, the yield can be improved while the display effect is improved, thus avoiding the risk of market withdrawal.

Other embodiments of the present disclosure will be apparent to those skilled in the art from consideration of the description and practice of the present disclosure. The present disclosure is intended to cover any variations, uses, or adaptations of the present disclosure following the general principles of the present disclosure and including the common knowledge and conventional technical means in the art that are no disclosed in the present disclosure. It is intended that the description and examples be considered as examples only, with a true scope and spirit of the present disclosure being indicated by the appended claims.

1. A display panel, comprising:
a driving backplane, provided with a display region and a peripheral region located at a periphery of the display region;
a first electrode layer, located on a side of the driving backplane and comprising an adapter electrode with an orthographic projection located in the peripheral region;
a pixel definition layer, located on a side of the first electrode layer away from the driving backplane;
a light-emitting functional layer, located on a side of the pixel definition layer away from the driving backplane, wherein an orthographic projection of the light-emitting functional layer covers the display region, an edge of the orthographic projection of the light-emitting functional layer is located in the peripheral region, and an orthographic projection of the adapter electrode is located outside the orthographic projection of the light-emitting functional layer; and
a second electrode layer, located on a side of the light-emitting functional layer away from the driving backplane and connected to the adapter electrode.

2. The display panel according to claim 1, wherein the light-emitting functional layer comprises:
a first common film layer, located on a side of the pixel definition layer away from the driving backplane, wherein an orthographic projection of the first common film layer covers the display region, an edge of the orthographic projection of the first common film layer is located in the peripheral region, and the orthographic projection of the adapter electrode is located outside the orthographic projection of the first common film layer;
a light-emitting material layer, located on a side of the first common film layer away from the driving backplane, and comprising a plurality of light-emitting material units with orthographic projections located in the display region; and
a second common film layer, located on a side of the light-emitting material layer away from the driving backplane, wherein an orthographic projection of the second common film layer covers the display region, an edge of the orthographic projection of the second common film layer is located in the peripheral region, and the orthographic projection of the adapter electrode is located outside the orthographic projection of the second common film layer.

3. The display panel according to claim 1, wherein the adapter electrode is provided with a first edge close to the display region and a second edge away from the display region; and
a distance between the edge of the orthographic projection of the light-emitting functional layer and an orthographic projection of the first edge is greater than or equal to 20 μm.

4. The display panel according to claim 3, wherein a distance between the edge of the orthographic projection of the light-emitting functional layer and an edge of the display region is greater than or equal to 60 μm and less than or equal to 180 μm.

5. The display panel according to claim 3, wherein a distance between the orthographic projection of the first edge and an edge of the display region is greater than or equal to 160 μm and less than or equal to 200 μm.

6. The display panel according to claim 3, wherein an edge of an orthographic projection of the pixel definition layer is located between the orthographic projection of the first edge and an orthographic projection of the second edge.

7. The display panel according to claim 6, wherein a distance between the edge of the orthographic projection of the pixel definition layer and the orthographic projection of the first edge is greater than or equal to 20 μm.

8. The display panel according to claim 1, wherein the adapter electrode is provided with a first edge close to the display region;
a distance between the edge of the orthographic projection of the light-emitting functional layer and an edge of the display region is a first distance, and a distance between an orthographic projection of the first edge and the edge of the display region is a second distance;
the second distance is greater than the first distance, and a ratio of the second distance to the first distance is greater than or equal to 1.1 and less than or equal to 1.5.

9. The display panel according to claim 8, wherein a distance between an edge of an orthographic projection of the pixel definition layer and the edge of the display region is a third distance; and
the third distance is greater than the second distance, and a ratio of the third distance to the second distance is greater than or equal to 1.1 and less than or equal to 1.5.

10. A method for manufacturing a display panel, comprising:
forming a driving backplane, wherein the driving backplane is provided with a display region and a peripheral region located at a periphery of the display region;
forming a first electrode layer on a side of the driving backplane, wherein the first electrode layer comprises an adapter electrode with an orthographic projection located in the peripheral region;
forming a pixel definition layer on a side of the first electrode layer away from the driving backplane;
forming a light-emitting functional layer on a side of the pixel definition layer away from the driving backplane by using at least one mask, wherein an orthographic projection of the light-emitting functional layer covers the display region, an edge of the orthographic projection of the light-emitting functional layer is located in the peripheral region, and an orthographic projection of the adapter electrode is located outside the orthographic projection of the light-emitting functional layer; and
forming a second electrode layer on a side of the light-emitting functional layer away from the driving backplane, wherein the second electrode layer at least covers the light-emitting functional layer and is connected to the adapter electrode.

11. The method according to claim 10, wherein forming the light-emitting functional layer on the side of the pixel definition layer away from the driving backplane by using the at least one mask comprises:
providing a first mask on a side of the pixel definition layer away from the driving backplane, and forming a first common film layer by using the first mask, wherein the first mask is provided a first evaporation hole, an orthographic projection of the first evaporation hole covers the display region, an edge of the orthographic projection of the first evaporation hole is located in the peripheral region, and an orthographic projection of the adapter electrode is located outside the orthographic projection of the first evaporation hole;
providing a second mask on a side of the first common film layer away from the driving backplane, and forming a light-emitting material layer by using the second mask, wherein the second mask is provided with a plurality of second evaporation holes, and orthographic projections of the plurality of second evaporation holes are located in the display region; and
providing a third mask on a side of the light-emitting material layer away from the driving backplane, and forming a second common film layer by using the third mask, wherein the third mask is provided with a third evaporation hole, an orthographic projection of the third evaporation hole covers the display region, an edge of the orthographic projection of the third evaporation hole is located in the peripheral region, and the orthographic projection of the adapter electrode is located outside the orthographic projection of the third evaporation hole.

12. A display apparatus, comprising a display panel, wherein the display panel comprises:
a driving backplane, provided with a display region and a peripheral region located at a periphery of the display region;
a first electrode layer, located on a side of the driving backplane and comprising an adapter electrode with an orthographic projection located in the peripheral region;
a pixel definition layer, located on a side of the first electrode layer away from the driving backplane;
a light-emitting functional layer, located on a side of the pixel definition layer away from the driving backplane, wherein an orthographic projection of the light-emitting functional layer covers the display region, an edge of the orthographic projection of the light-emitting functional layer is located in the peripheral region, and an orthographic projection of the adapter electrode is located outside the orthographic projection of the light-emitting functional layer; and
a second electrode layer, located on a side of the light-emitting functional layer away from the driving backplane and connected to the adapter electrode.

13. The display apparatus according to claim 12, wherein the light-emitting functional layer comprises:
a first common film layer, located on a side of the pixel definition layer away from the driving backplane, wherein an orthographic projection of the first common film layer covers the display region, an edge of the orthographic projection of the first common film layer is located in the peripheral region, and the orthographic projection of the adapter electrode is located outside the orthographic projection of the first common film layer;
a light-emitting material layer, located on a side of the first common film layer away from the driving backplane, and comprising a plurality of light-emitting material units with orthographic projections located in the display region; and
a second common film layer, located on a side of the light-emitting material layer away from the driving backplane, wherein an orthographic projection of the second common film layer covers the display region, an edge of the orthographic projection of the second common film layer is located in the peripheral region, and the orthographic projection of the adapter electrode is located outside the orthographic projection of the second common film layer.

14. The display apparatus according to claim 12, wherein the adapter electrode is provided with a first edge close to the display region and a second edge away from the display region; and
a distance between the edge of the orthographic projection of the light-emitting functional layer and an orthographic projection of the first edge is greater than or equal to 20 μm.

15. The display apparatus according to claim 14, wherein a distance between the edge of the orthographic projection of the light-emitting functional layer and an edge of the display region is greater than or equal to 60 μm and less than or equal to 180 μm.

16. The display apparatus according to claim 14, wherein a distance between the orthographic projection of the first edge and an edge of the display region is greater than or equal to 160 μm and less than or equal to 200 μm.

17. The display apparatus according to claim 14, wherein an edge of an orthographic projection of the pixel definition layer is located between the orthographic projection of the first edge and an orthographic projection of the second edge.

18. The display apparatus according to claim 17, wherein a distance between the edge of the orthographic projection of the pixel definition layer and the orthographic projection of the first edge is greater than or equal to 20 μm.

19. The display apparatus according to claim 12, wherein the adapter electrode is provided with a first edge close to the display region;
a distance between the edge of the orthographic projection of the light-emitting functional layer and an edge of the display region is a first distance, and a distance between an orthographic projection of the first edge and the edge of the display region is a second distance;
the second distance is greater than the first distance, and a ratio of the second distance to the first distance is greater than or equal to 1.1 and less than or equal to 1.5.

20. The display apparatus according to claim 19, wherein a distance between an edge of an orthographic projection of the pixel definition layer and the edge of the display region is a third distance; and
the third distance is greater than the second distance, and a ratio of the third distance to the second distance is greater than or equal to 1.1 and less than or equal to 1.5.
